(19) United States
(12) Patent Application Publication
(10) Pub. No.: US 2026/0052960 A1
(43) Pub. Date: Feb. 19, 2026

(54) LOW RESISTIVITY AND LOW SURFACE ROUGHNESS TUNGSTEN GROWTH ON BORON NITRIDE INTERFACE

(71) Applicant: Applied Materials, Inc., Santa Clara, CA (US)

(72) Inventors: Yao XU, Santa Clara, CA (US); Xi CEN, San Jose, CA (US); Kai WU, Palo Alto, CA (US); Cheng CHENG, Santa Clara, CA (US); Rongjun WANG, Dublin, CA (US); Xianmin TANG, San Jose, CA (US)

(21) Appl. No.: 19/041,484

(22) Filed: Jan. 30, 2025

Related U.S. Application Data
(60) Provisional application No. 63/682,754, filed on Aug. 13, 2024.

(51) Int. Cl. H01L 21/768; C23C 16/44; C23C 16/455; H01L 23/532

(52) U.S. Cl. CPC H01L 21/76876; C23C 16/45553; H01L 21/76826; H01L 21/76843; H01L 21/76877; H01L 23/53266; C23C 16/4408

(57) ABSTRACT

Methods used in electronic device manufacturing and, more particularly, to methods used for forming metal containing interconnect features in a semiconductor device. In one aspect, a method of forming a boron nitride layer on a metal surface is provided. The method includes exposing a surface of a metal layer to a nitrogen-containing plasma to form a metal nitride layer on the surface. The method further includes performing a chemical vapor deposition (CVD) soak process in which the metal nitride layer is exposed to a boron (B)-containing precursor gas, form a boron nitride monolayer.

### CROSS-REFERENCE TO RELATED APPLICATIONS

This application claims the benefit of U.S. Provisional Patent Application Ser. No. 63/682,754, filed Aug. 13, 2024, which is incorporated by reference herein in its entirety.

### BACKGROUND

### Field

Implementations of the present disclosure generally relate to methods used in electronic device manufacturing and, more particularly, to methods used for forming metal containing interconnect features in a semiconductor device.

### Description of the Related Art

Tungsten (W) is widely used in integrated circuit (IC) device manufacturing to form conductive features where relatively low electrical resistance and relativity high resistance to electromigration are targeted. For example, tungsten may be used as a metal fill material to form source contacts, drain contacts, metal gate fill, gate contacts, interconnects, for example, horizontal features formed in a surface of a dielectric material layer, and vias, for example, vertical features formed through a dielectric material layer to connect other interconnect features disposed there above and there below. Due to the relativity low resistivity of tungsten, tungsten is generally used to form bit lines and word lines used to address individual memory cells in a memory cell array of a dynamic random-access memory (DRAM) device.

As critical dimensions on IC devices shrink, past fabrication techniques encounter new hurdles. For example, during filling of a feature with tungsten, the tungsten fill layer can deposit in an upper portion of the feature quicker than a lower portion due to the varying feature widths and higher concentration of precursor gases used to deposit the tungsten fill layer. This can cause void formation within portions of the feature, particularly for high aspect ratio features.

Accordingly, there is a need for processes to fill features with tungsten that are free or substantially free of voids and seams and have low resistivity for various film thicknesses.

### SUMMARY

In one aspect, a method of forming a boron nitride layer on a metal surface is provided. The method includes exposing a surface of a metal layer to a nitrogen-containing plasma to form a metal nitride layer on the surface. The method further includes performing a chemical vapor deposition (CVD) soak process in which the metal nitride layer is exposed to a boron (B)-containing precursor gas, form a boron nitride monolayer.

Implementations can include one or more of the following. The metal is tantalum, cobalt, titanium, tungsten, copper, ruthenium, molybdenum, or a combination thereof. The nitrogen-containing plasma is formed from a process gas including a nitrogen-containing gas. The nitrogen-containing gas is N2, NO, NO2, NH3, N2H4, or a combination thereof. The process gas further includes an inert gas. The inert gas is argon, helium, or a combination thereof. The metal layer is a nucleation layer formed on a surface of a high aspect ratio feature. The metal layer is a capping layer. The method further includes repeating for a number of cycles exposing the surface of the metal layer to the nitrogen-containing plasma and exposing the metal nitride layer to a boron containing precursor gas to form a three-dimensional boron nitride layer. The boron containing precursor gas is diborane, Triethylborane, Diethylborane, borazine (B3H6N3), or a combination thereof.

In another aspect, a method of filling a feature is provided. The method includes forming a nucleation layer over a surface of a feature formed in a surface of a substrate. The nucleation layer includes a metal and the metal is tungsten, molybdenum, or cobalt. The surface of the feature has a bottom surface and a sidewall surface. The sidewall surface has a bottom portion and a top portion, which is above the bottom portion. The method further includes exposing the formed nucleation layer to a nitrogen-containing plasma to form a metal nitride layer on the surface of the nucleation layer. The metal nitride layer includes a gradient in nitrogen composition from the top portion to the bottom portion of the sidewall surface. The method further includes forming a boron nitride layer on the formed metal nitride layer by soaking the formed metal nitride layer in a first amount of a boron containing precursor gas. The method further includes exposing the substrate to a metal-containing precursor gas and a reducing agent to form a metal fill layer over the formed boron nitride layer, wherein the metal fill layer includes a metal and the metal is tungsten, molybdenum, cobalt, or a combination thereof.

Implementations can include one or more of the following. The nitrogen-containing plasma is formed from a process gas including a nitrogen-containing gas. The nitrogen-containing gas is N2, NO, NO2, NH3, N2H4, or a combination thereof. The process gas further includes an inert gas. The inert gas is argon, helium, or a combination thereof. A liner layer is formed on the surface of the feature prior to forming the nucleation layer. The boron nitride layer is a boron nitride monolayer.

In yet another aspect, a method of filling a feature is provided. The method includes forming a tungsten nucleation layer over a surface of a feature formed in a surface of a substrate. The surface of the feature has a bottom surface and a sidewall surface. The sidewall surface has a bottom portion and a top portion, which is above the bottom portion. The method further includes exposing the tungsten nucleation layer to a nitrogen-containing plasma to form a tungsten nitride layer on the surface of the tungsten nucleation layer. The tungsten nitride layer includes a gradient in nitrogen composition from the top portion to the bottom portion of the sidewall surface and the nitrogen-containing plasma is formed from a process gas including ammonia. The method further includes forming a boron nitride layer on the tungsten nitride layer by soaking the tungsten nitride layer in a first amount of diborane. The method further includes exposing the substrate to a tungsten-containing precursor gas and a reducing agent to form a tungsten fill layer over the boron nitride layer.

Implementations can include one or more of the following. The method further includes forming a liner layer on the surface of the feature prior to forming the tungsten nucleation layer. The nitrogen-containing plasma is formed from a process gas including a nitrogen-containing gas. The nitrogen-containing gas is N2, NO, NO2, NH3, N2H4, or a combination thereof. The process gas further includes an inert gas. The inert gas is argon, helium, or a combination thereof. A liner layer is formed on the surface of the feature prior to forming the nucleation layer. The boron nitride layer is a boron nitride monolayer.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, and may admit to other equally effective implementations.

FIG. 1 is a flowchart illustrating a method of forming a boron nitride film for a semiconductor device structure, in accordance with one or more implementations of the present disclosure.

FIGS. 2A-2D illustrate schematic views of various stages of forming a semiconductor device structure incorporating a boron nitride film, in accordance with one or more implementations of the present disclosure.

FIG. 3 is a flowchart illustrating a method of manufacturing a semiconductor device structure incorporating a boron nitride film, in accordance with one or more implementations of the present disclosure.

FIGS. 4A-4H illustrate schematic views of various stages of forming a semiconductor device structure incorporating a boron nitride film, in accordance with one or more implementations of the present disclosure.

FIG. 5 illustrates a schematic top view of one example of a multi-chamber processing system in accordance with one or more implementations of the present disclosure.

FIG. 6 depicts a graph illustrating the effect of adjusting the nitrogen concentration during the N-treatment process on incubation time of the deposited tungsten film in accordance with one or more implementations of the present disclosure.

FIG. 7 depicts a graph illustrating the resistivity benefit provided by different process sequences in accordance with one or more implementations of the present disclosure.

### DETAILED DESCRIPTION

Implementations herein are generally directed to electronic device manufacturing and, more particularly, to systems and methods for forming low resistivity contacts in a semiconductor device manufacturing scheme.

As circuit densities increase and device features continue to shrink to meet the demands of the next generation of semiconductor devices, reliably producing tungsten features has become increasingly challenging. Issues such as voids and seams formed during a conventional tungsten deposition process become amplified with decreasing feature size and can detrimentally affect the performance and reliability of a device or even render a device inoperable.

Moving forward future generations, the metal contact structure shrinks its critical dimension (CD) into a nanometer (nm) region with a high aspect ratio (>20:1). To achieve good step coverage and void or seam-free gap fill seam suppression or field inhibition capability is mandatory for VLSI metallization.

With the demand for metal fill in the small critical size and higher aspect ratio features, the conventional growth process (conformal CVD W) was not suitable due to early pinch-off at the top of the gap leaving large voids or seams inside the structure. The SSW (seam-suppression-W) methods with inhibition on the field was widely used to improve gap fill. However, the inhibitor in SSW methods generally forms a WN interface, which causes the resistivity of the metal contact to increase drastically. In addition, due to the non-uniformity of the inhibition layer, the subsequently grown tungsten film has bigger grain size and is rougher. The increased roughness leads to stitching fault at via closing and, hence, large quantities of large post CMP keyholes.

Implementations of the present disclosure include a new method of growing a BN interface layer on metal (W) layer by PECVD. In some implementations, the metal layer can be a refractory metal, such as W, Mo or Co. On the metal layer (e.g., W, Mo, or Co nucleation layer) a nitrogen plasma (N₂) is used to treat the surface of the metal layer to form a metal nitride (e.g., WN, MoN, or CoN). The metal nitride can have a gradient in nitrogen concentration from the bottom to the top of the feature. Then a gas phase boron source soak process is performed on the formed metal nitride. It is believed that the boron precursor, for example, diborane (B₂H₆), Triethylborane (TEB), Diethylborane (DEB), evaporated boron bulk, then reacts with surface N atoms to form the BN interface. Since the N atoms in the metal nitride layer are only present on the surface of the metal nitride layer, the formation of BN is self-limiting and thus will only form a thin BN layer, for example, a BN monolayer.

The hexagonal boron nitride (h-BN) monolayers described, which include atomically thin sp2-hybridized sheets, can be readily synthesized on various metal support structures. It is believed that forming h-BN by PECVD by use of a nitrogen (N) plasma and then growing tungsten on a BN interface layer can be useful to address issues such as the roughness caused by metal nitride incubation and increased resistivity.

In addition, because the N radicals react with surface metal atoms, the boron soak only reacts with surface N atoms forming a self-limiting BN monolayer. This BN layer has intrinsic mesopores, which can provide a template for other applications including energy storage, optical modulation, DNA sequencing, and quantum information technologies. The BN interface layer also has low dangling bonds, which provides a good substrate for chemical reactions. The BN interface layer can also change the surface of metal from hydrophilic to hydrophobic.

Further, cycles of N plasma and boron soaking can be repeated to increase the thickness of BN cap. Multiple BN interface layers can be stacked with weak Van der Waals bonds that can be a surface coat with low friction and lubrication. BN interface layer with a large bandgap (>5.5 eV) can serve as insulator layer or dielectric layers for semiconductor devices. BN cap provides good oxygen insulation cap from exposing the metal surface to atmosphere.

By controlling the amount of boron soak dosage, the portion of the WN that will react with the boron precursor to form BN on metal nitride layer can be controlled. The unreacted WN provides the inhibition for the following metal growth and, hence, preserves the seam suppression capability. In addition, the BN interface provides good adhesion for the subsequently deposited metal film. Compared to directly soak B₂H₆ on a metal nitride layer, the unreacted WN provides sufficient adhesion to the subsequently deposited CVD W film. The CVD film growth on BN interface passed the adhesion test while the B₂H₆ soak interface failed. It has been found that W grown on BN interface layer will include large planar grains. Such large planar grains reduced electron scattering at the grain boundary and demonstrated a lower resistivity than traditionally formed W films (conformal CVD W or SSW), as shown in FIG. 7. Such resistivity benefit was confirmed in both the thin film region (<500 A) and the bulk metal region (>2000 A). The formed large planar grains also reduced the W film roughness. The smooth W film is favorable for the subsequent CMP process and reduces the risk of grain stitching faults or large post-CMP keyholes. In addition, the integration can be performed in multiple tools, or integrated into a single system. Multiple chamber or one chamber could either work depending on requirement and structure dimension.

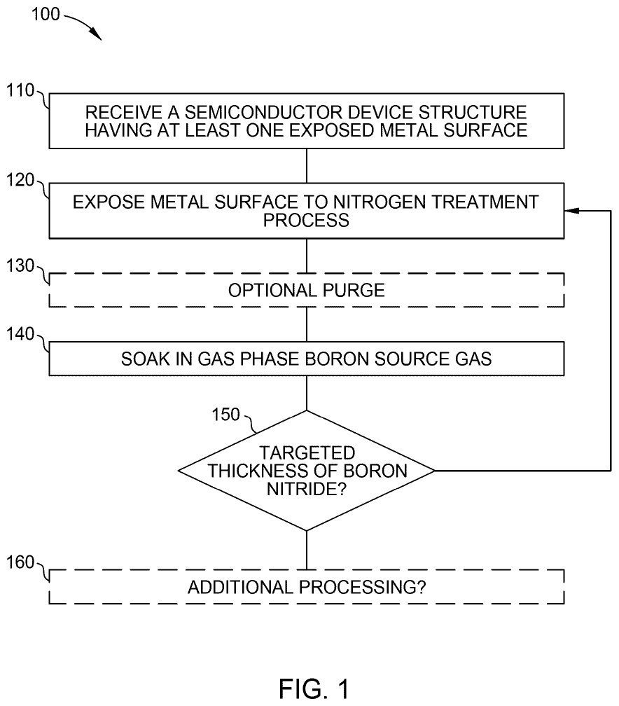

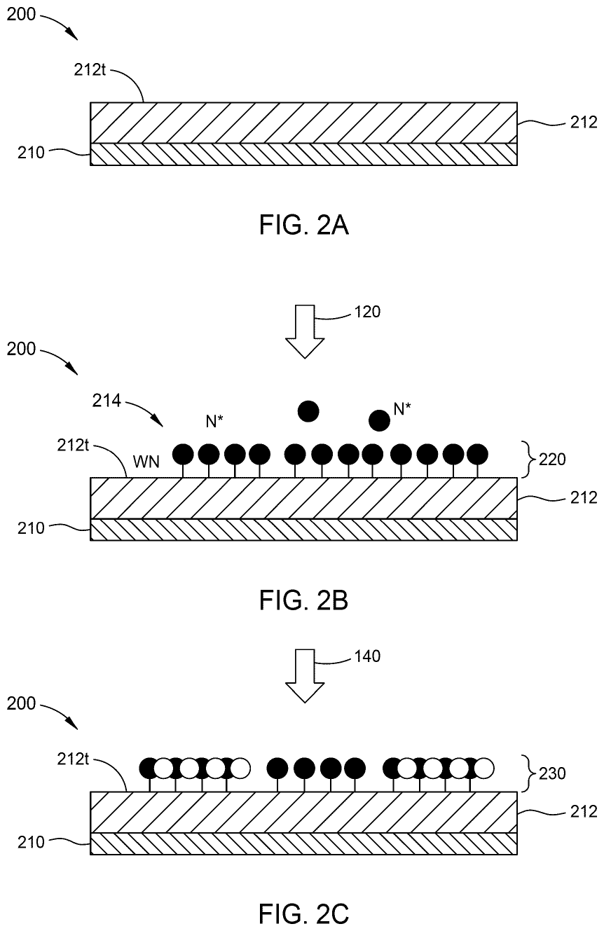

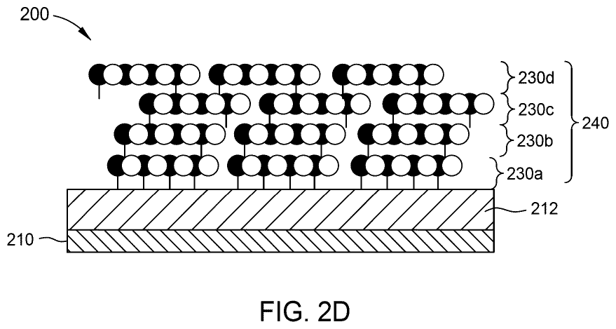

FIG. 1 is a flow diagram depicting a method of forming a boron nitride film for a semiconductor device structure, in accordance with one or more implementations of the present disclosure. FIGS. 2A-2D illustrate views of various stages of forming a semiconductor device structure incorporating a boron nitride film, in accordance with one or more implementations described herein. Although FIGS. 2A-2D are described in relation to the method 100, the structures disclosed in FIGS. 2A-2D are not limited to the method 100, but instead may stand alone as structures that are independent of the method 100. Similarly, although the method 100 is described in relation to FIGS. 2A-2D, the method 100 is not limited to the structures disclosed in FIGS. 2A-2D but instead may stand alone independent of the structures disclosed in FIGS. 2A-2D. It should be understood that FIGS. 2A-2D illustrate only partial schematic views of the semiconductor device structure 200, and the semiconductor device structure 200 may contain any number of transistor sections and additional materials having aspects as illustrated in the figures. It should also be noted that although the method 100 illustrated in FIG. 1 is described sequentially, other process sequences that include one or more operations that have been omitted and/or added, and/or has been rearranged in another desirable order, fall within the scope of the implementations of the disclosure provided herein.

At operation 110, a semiconductor device structure is received. The semiconductor device structure may be the semiconductor device structure 200 as shown in FIG. 2A. The semiconductor device structure 200 may be positioned on a substrate support of a plasma processing system.

Referring to FIG. 2A, the semiconductor device structure 200 includes a device substrate 210 having a metal layer 212 formed thereon. The metal layer 212 includes a metal surface 212t, which is an exposed surface. The device substrate 210 may be or include a bulk semiconductor substrate, a semiconductor-on-insulator (SOI) substrate, or the like, which may be doped, for example, with a p-type dopant or an n-type dopant, or undoped. In some implementations, the semiconductor material of the device substrate 210 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 210 may include additional materials, for example, silicide layers, metal silicide layers, metal layers, dielectric layers, etch stop layers, interlayer dielectrics, or a combination thereof.

The device substrate 210 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 210 to generate the structural and functional requirements of the design for the resulting semiconductor device structure 200.

In one or more implementations, the metal layer 212 is or includes a refractory metal. In one or more implementations, the metal layer 212 is tantalum (Ta), cobalt (Co), titanium (Ti), tungsten (W), copper (Cu), ruthenium (Ru), molybdenum (Mo), or a combination thereof. In one or more implementations, the metal layer 212 is tungsten (W), molybdenum (Mo), cobalt (Co), or a combination thereof. The metal layer 212 can have a thickness in a range from about 1 Å to about 200 Å, or in a range from about 10 Å to about 100 Å, or in a range from about 20 Å to about 50 Å. The metal layer 212 may be formed by any suitable process, including but not limited to, atomic layer deposition (ALD), chemical vapor deposition (CVD), plasma-enhanced CVD (PECVD), physical vapor deposition (PVD), electroplating, or electroless plating.

Referring to FIG. 2B, at operation 120, the metal surface 212t of the metal layer 212 is exposed to a nitrogen treatment process. The nitrogen treatment process or operation 120 can be or include a plasma-based nitrogen treatment or a thermal-based nitrogen treatment. Exposing the metal surface 212t to the nitrogen treatment process forms a metal nitride layer 214 on the metal surface 212t. The metal nitride layer 214 includes a first monolayer of nitrogen atoms 220.

In one or more implementations, the nitrogen treatment process of operation 120 is a plasma-based nitrogen treatment. The plasma can be a radio frequency (RF) plasma, for example, an inductively couple plasma (ICP) or a capacitively coupled plasma (CCP). The plasma can be formed using a remote plasma source (RPS) and delivered to the processing region including the semiconductor device structure 200. The plasma can be an in-situ plasma formed in the processing region including the semiconductor device structure 200. In some implementations, the nitrogen plasma treatment process includes exposing the metal surface 212t to a plasma formed from a process gas including a nitrogen-containing gas. The nitrogen-containing gas is or includes N2, NH3, N2H4, or a combination thereof. The process gas can further include an inert gas, for example, argon (Ar), helium (He), krypton (Kr), or a combination thereof. The process gas may include argon (Ar), helium (He) hydrogen (H2), nitrogen (N2), or a H2/N2 mixture. In one or more implementations, the plasma treatment process includes exposing the metal surface 212t to an ICP formed from a process gas including a nitrogen-containing gas, for example, N2, and an inert gas, for example, argon. In one or more implementations, the plasma treatment process can include exposing the metal surface 212t to a plasma formed in a RPS form a process gas including one or more of N2 and Ar. In one or more implementations, the nitrogen plasma treatment process can include exposing the nucleation layer to a plasma including either substantially radicals (nitrogen radicals) or substantially ions (nitrogen ions).

The plasma process of operation 120 can be performed while maintaining a pressure in a range from about 1 Torr to about 20 Torr, for example, from about 1 Torr to about 10 Torr, from about 1 Torr to about 8 Torr, or from about 1 Torr to about 5 Torr. In one or more implementations, the plasma process of operation 120 may be performed while maintaining a temperature in a range from about 300° C. to about 700° C., for example, from about 400° C. to about 700° C., or from about 400° C. to about 650° C., or from about 550° C. to about 650° C. In one or more implementations, the plasma process of operation 120 may be performed while operating the plasma source at a power in a range from about 50 W to about 12 kW, for example, from about 5 kW to about 10 kW, or from about 5 kW to about 8 kW, from about 6 kW to about 8 kW, or from about 7 kW to about 8 kW. The RF source power may be provided at any suitable RF frequency. In one or more implementations, the RF source power may be provided at a frequency about 2 to about 60 MHz, for example, about 13.56 MHz.

In one or more implementations, the nitrogen treatment process of operation 120 is a thermal-based nitrogen treatment or nitrogen soak process. The nitrogen soak process is a gas phase nitrogen source soak process performed on the metal surface 212t to form the metal nitride layer 214. In one or more implementations, the nitrogen source gas is nitrogen trifluoride (NF3), ammonia (NH3), nitrogen (N2), or a combination thereof. The nitrogen soak process may include introducing additional gases into the processing region, for example, hydrogen (H2) gas.

In one or more implementations, the nitrogen soak process is performed at a temperature in a range from about 100 degrees Celsius to about 600 degrees Celsius, or in a range from about 200 degrees Celsius to about 500 degrees Celsius, or in a range from about 250 degrees Celsius to about 450 degrees Celsius. The nitrogen soak process can be performed at a pressure in a range from about 1 Torr to about 150 Torr, or in a range from about 1 Torr to about 100 Torr, or in a range from about 5 Torr to about 90 Torr, or in a range from about 5 Torr to about 20 Torr. The nitrogen soak process can be performed for a period of time in a range from about 5 seconds to about 90 seconds, or in a range from about 5 seconds to about 60 seconds, or in a range from about 5 seconds to about 20 seconds.

Optionally, at operation 130, in some implementations where operation 120 and 140 are performed in the same processing region, after operation 120 and prior to operation 140, a purge process is performed to remove any remaining plasma gases and any byproducts from the processing region. For example, plasma gases and reaction byproducts (if any) may be removed from the surface of the semiconductor device structure 200, for example, by pumping with inert gas. In some implementations, where an inert carrier gas is introduced into the processing region with the nitrogen-containing gas, the flow of the nitrogen-containing gas may be stopped while the inert carrier gas continues to flow to purge the processing region. In some implementations, excess vapor phase reactants, such as for example, excess nitrogen-containing gas, plasma effluents, and possible reaction byproducts may be removed with the aid of a vacuum, generated by a pumping system in fluid communication with the processing region.

Referring to FIG. 2C, at operation 140, then a gas phase boron source soak process is performed on the formed metal nitride. It is believed that the boron precursor then reacts with the first monolayer of nitrogen atoms 220 to form a BN interface monolayer 230 on the metal surface 212t. Because the N atoms in the metal nitride layer are only present on the metal surface 212t, the formation of the BN interface monolayer 230 is self-limiting and thus will only form a thin BN monolayer.

In one or more implementations, the boron source gas is diborane (B₂H₆), Triethylborane (TEB), Diethylborane (DEB), evaporated boron bulk, borazine (B3H6N3), or a combination thereof. The boron source gas may be delivered to the processing region by a carrier gas. In one or more implementations, the carrier gas is hydrogen (H2) gas. The flow rate of boron source gas is generally in a range from about 1 sccm to about 2,000 sccm, or from about 1 sccm to about 1,000 sccm, or from about 10 sccm to about 1,000 sccm, or from about 50 sccm to about 500 sccm.

In one or more implementations, the metal nitride is exposed to a soak process at a temperature in a range from about 100 degrees Celsius to about 600 degrees Celsius, or in a range from about 200 degrees Celsius to about 500 degrees Celsius, or in a range from about 250 degrees Celsius to about 500 degrees Celsius, or in a range from about 250 degrees Celsius to about 450 degrees Celsius. The soak process is typically performed at a pressure in a range from about 1 Torr to about 150 Torr, or in a range from about 1 Torr to about 100 Torr, or in a range from about 5 Torr to about 90 Torr, or in a range from about 5 Torr to about 20 Torr. The soak is usually for a period of time in a range from about 5 seconds to about 90 seconds, or in a range from about 5 seconds to about 60 seconds, or in a range from about 5 seconds to about 20 seconds. In another aspect, the soak will last for about 10 seconds.

At operation 150, it is determined whether a targeted thickness of the BN interface monolayer 230 has been achieved. For example, in implementations where a BN monolayer is targeted, one cycle of operations 120, 130 and 140 is performed to form the two-dimensional BN interface monolayer 230. However, if a three-dimensional BN interface layer is targeted, multiple cycles of operations 120, 130 and 140 are performed. For example, referring to FIG. 2D, a three-dimensional BN layer 240 or capping layer including multiple two-dimensional BN interface monolayers 230a-d is formed. After the targeted thickness of the BN layer is achieved, the semiconductor device structure 200 may be exposed to additional processing at operation 160.

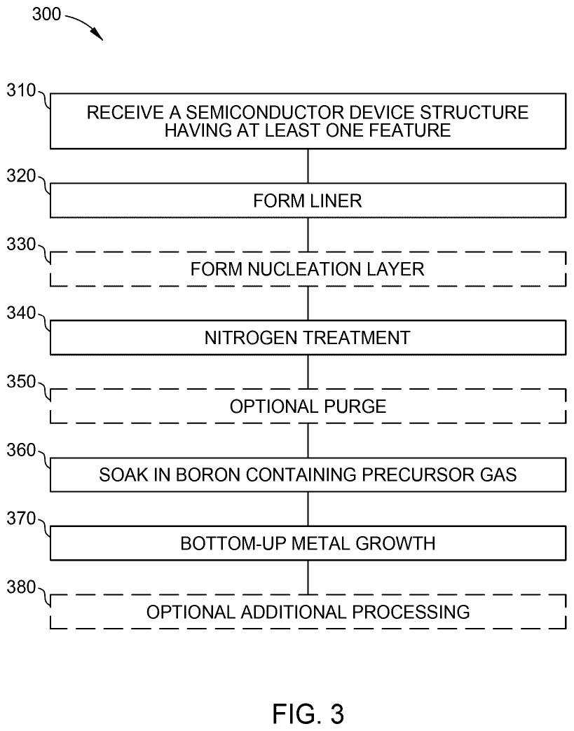

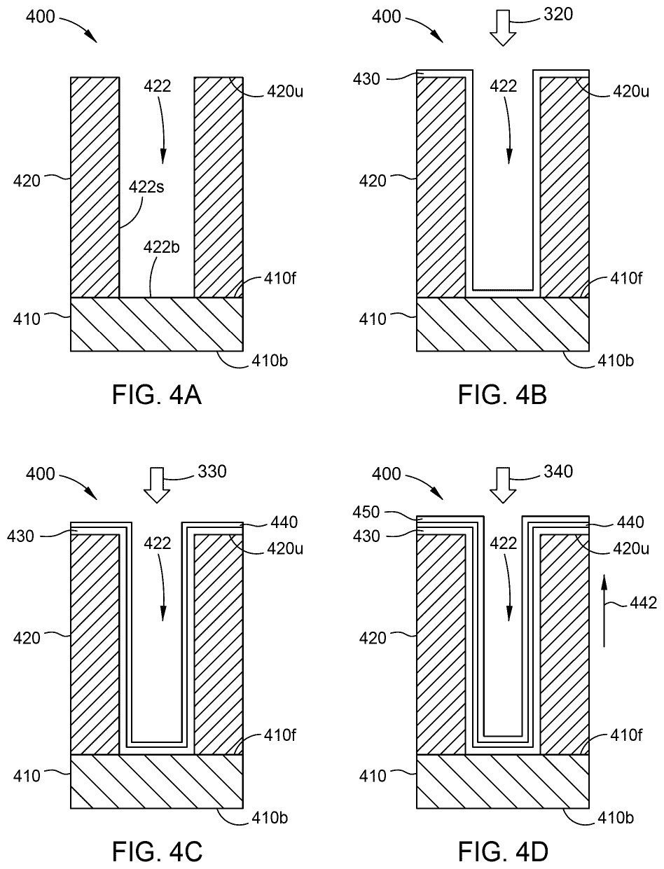

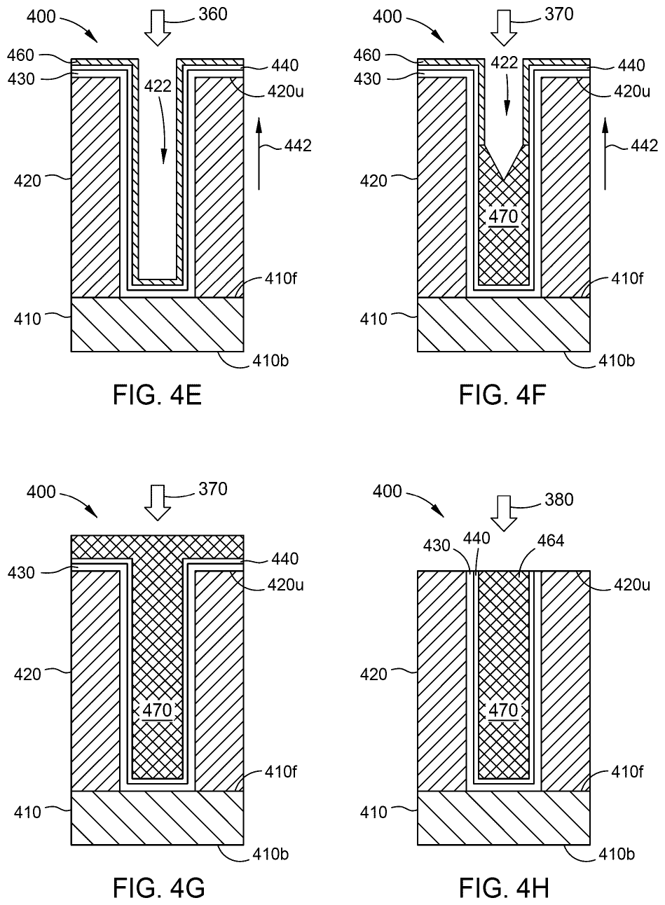

FIG. 3 is a flow diagram depicting a method of forming a semiconductor device structure incorporating a boron nitride film, in accordance with one or more implementations of the present disclosure. FIGS. 4A-4F illustrate views of various stages of forming a semiconductor device structure incorporating a boron nitride film, in accordance with one or more implementations described herein. Although FIGS. 4A-4F are described in relation to the method 300, the structures disclosed in FIGS. 4A-4F are not limited to the method 300, but instead may stand alone as structures that are independent of the method 300. Similarly, although the method 300 is described in relation to FIGS. 4A-4F, the method 300 is not limited to the structures disclosed in FIGS. 4A-4F but instead may stand alone independent of the structures disclosed in FIGS. 4A-4F. It should be understood that FIGS. 4A-4F illustrate only partial schematic views of the semiconductor device structure 400, and the semiconductor device structure 400 may contain any number of transistor sections and additional materials having aspects as illustrated in the figures. It should also be noted that although the method 300 illustrated in FIG. 3 is described sequentially, other process sequences that include one or more operations that have been omitted and/or added, and/or has been rearranged in another desirable order, fall within the scope of the implementations of the disclosure provided herein.

Referring to FIG. 4A, at operation 310, a semiconductor device structure 400 having at least one feature 422 is received. The semiconductor device structure 400 includes a device substrate 410 having one or more layers formed thereon, for example, a dielectric layer 420 as is shown in FIG. 4A. The device substrate 410 may be similar to the device substrate 210. The device substrate 410 has a frontside 410f (also referred to as a front surface) and a backside 410b (also referred to as a back surface) opposite the frontside 410f. The dielectric layer 420 is formed over the frontside 410f of the device substrate 410. The dielectric layer 420 may include multiple layers. The dielectric layer 420 includes an upper surface 420u or field region. In some implementations, the dielectric layer 420 includes silicon oxide, silicon oxynitride, silicon nitride, a combination thereof, or multi-layers thereof. In some implementations, the dielectric layer 420 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 420 is patterned to form one or more feature(s) 422. The feature 422 may be a high aspect ratio (HAR) feature. In some implementations, the feature 422 can be selected from a trench, a via, a hole, or combinations thereof. In particular implementations the feature 422 is a via. In some implementations, the feature 422 extends from the upper surface 420u of the dielectric layer 420 to the frontside 410f of the device substrate 410. The feature 422 includes sidewall surface 422s and a bottom surface 422b extending between the sidewall surface 422s. In some implementations, the sidewall surface 422s is tapered. The sidewall surface 422s may be defined by the dielectric layer 420 and the bottom surface may be defined by the device substrate 410. In some implementations, the sidewall surface 422s may be defined by the dielectric layer 420 and the bottom surface may also be defined by the dielectric layer 420. The feature 422 has a first depth “D1” from the upper surface 420u to the bottom surface 422b and a width “W1” between the two sidewall surface 422s. In some implementations, the feature 422 can include one or a combination of high aspect ratio via or trench openings having a width W1 of about 1 μm or less, such as about 800 nm or less, or about 500 nm or less, and a depth D1 of about 2 μm or more, such as about 3 μm or more, such as about 4 μm or more, such as about 8 μm or more. In some implementations, each of the openings had an aspect ratio (depth to width ratio) of about 3:1 or more, such as about 5:1 or more, such as about 10:1 or more, such as about 50:1 or more, such as about 70:1 or more. In some implementations, the vias or trench openings are about 20 nm to about 50 nm having aspect ratios of about 3:1 to about 10:1.

Referring to FIG. 4B, at operation 320, one or more conformal/nonconformal layers 430 may be formed over the surfaces of the feature 422. The one or more conformal/nonconformal layers 430 can include one or more barrier, adhesion, and/or liner layers. The one or more conformal/nonconformal layers 430 can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, the like, or a combination thereof, or a carbide, for example, tungsten carbide, aluminum carbide, the like, or a combination thereof. The one or more conformal/nonconformal layers 430 may be formed by a conformal/nonconformal layer deposition process. The one or more conformal/nonconformal layers 430 may be formed by any suitable conformal/nonconformal layer deposition process such as ALD, CVD, PVD, or a hybrid ALD/CVD process.

The one or more conformal/nonconformal layers 430 may be formed over the sidewall surface 422s and the bottom surface 422b of the feature 422 and on the upper surface 420u or field region of the dielectric layer 420. In some implementations, the one or more conformal/nonconformal layers 430 include a barrier layer having a liner layer formed thereon, for example, a titanium nitride barrier layer having a tungsten liner formed thereon. In some implementations, the one or more conformal/nonconformal layers 430 include a liner layer formed over the surfaces of the feature 422. The one or more conformal/nonconformal layers 430 may include or be a liner layer. The liner layer may be a titanium nitride liner layer. The liner layer may have an initial thickness in a range from about 1 Å to about 100 Å, or in a range from about 20 Å to about 50 Å. In some implementations, the one or more conformal/nonconformal layers 430 may be discontinuous along for example, the sidewall surface 422s and/or the bottom surface 422b. In particular implementations, the one or more conformal/nonconformal layers 430 include a titanium nitride liner layer, which is formed via a PVD process.

Referring to FIG. 2C, at operation 330, a nucleation layer, for example, a nucleation layer 440 is formed over the surfaces of the feature 422, for example, over the surface of the one or more conformal/nonconformal layers 430. The nucleation layer 440 may function as a seed layer for subsequent deposition of the metal-fill material. In addition, in some implementations where the previously deposited one or more conformal/nonconformal layers 430 are discontinuous, for example, along the sidewall surface 422s, the nucleation layer 440 may repair discontinuous portions of the one or more conformal/nonconformal layers 430. The nucleation layer 440 may include or be any suitable material for facilitating the growth of the subsequently deposited metal-fill material. In one or more implementations, the nucleation layer 440 can include or be a metal, for example, tungsten, molybdenum, cobalt, tantalum, titanium, ruthenium, the like, or a combination thereof. In one or more implementations, the nucleation layer 440 can include or be a metal, for example, tungsten, molybdenum, cobalt, or a combination thereof. In particular implementations, the nucleation layer 440 is tungsten. The nucleation layer 440 may be formed by a nucleation layer deposition process. Any suitable nucleation layer deposition process such as ALD, PEALD, PECVD, PVD, or a hybrid ALD/CVD process may be used. In one or more implementations, the nucleation layer 240 has a thickness in a range from about 10 Å to about 200 Å, or in a range from about 20 Å to about 100 Å, or in a range from about 30 Å to about 50 Å. In one or more implementations, the nucleation layer 440 is a tungsten layer formed by an ALD process having a thickness in a range from about 30 Å to about 50 Å.

Referring to FIG. 4D, at operation 340, a nitrogen treatment process is performed. The nitrogen treatment process can be a plasma-based nitrogen treatment or a thermal-based nitrogen treatment. The nitrogen treatment process of operation 340 can be performed similarly to the nitrogen treatment process of operation 120. The nitrogen treatment process of operation 340 forms a metal nitride layer 450 on the nucleation layer 440. The metal nitride layer 450 is formed by exposing the metal of the nucleation layer 440 to the nitrogen treatment process. The metal nitride layer 450 includes a monolayer of nitrogen molecules. The metal nitride layer 450 can have a dosage gradient 442 in nitrogen concentration, which increases from the bottom surface 422b of the feature 422 to the upper surface 420u of the feature 422 meaning that concentration of nitrogen near the bottom surface 422b is lighter and the concentration of nitrogen near the upper surface 420u is heavier.

Optionally at operation 350 in some implementations where operation 340 and operation 360 are performed in the same processing region, after operation 340 and prior to operation 360, a purge process is performed to remove any remaining plasma gases and any byproducts from the processing region. The purge process may be performed similarly to operation 130.

Referring to FIG. 4E, at operation 360, a boron soak process is performed. The boron soak process is a gas phase boron source soak process performed on the formed metal nitride layer 450 to form the BN interface layer 460. The BN interface layer 460 can be a BN monolayer. The BN interface layer 460 can be a hexagonal boron nitride layer (h-BN). It is believed that the boron precursor reacts with the surface N atoms of the metal nitride layer 450 to form the BN interface layer 460. Because the N atoms in the metal nitride layer 450 are only present on the surface of the metal nitride layer, the formation of BN is self-limiting and thus will only form a thin BN layer, for example, a monolayer of BN. The soak process of operation 360 can be performed similarly to the boron soak process of operation 140.

Referring to FIG. 4F, at operation 370, a metal-fill material 470, for example, a tungsten-fill material is optionally deposited via a metal-fill process, at least partially, into the feature 422. As shown in FIG. 4F, the BN interface layer 460 provides a growth gradient, which enables bottom-up growth of the metal-fill material 470. In some implementations, the metal-fill material 470 is formed using a PECVD process or a CVD process comprising concurrently flowing (co-flowing) a tungsten-containing precursor gas, and a reducing agent into the processing region and exposing the semiconductor device structure 400 thereto. The tungsten-containing precursor and the reducing agent used for the tungsten-fill CVD process may include any combination of the tungsten-containing precursors and reducing agents. In some implementations, the tungsten-containing precursor includes WF_{6,} and the reducing agent includes hydrogen gas. In some implementations, the metal-fill material 470 partially fills the features 422.

In some implementations, the tungsten-fill CVD process conditions are selected to provide a tungsten feature having a relativity low residual film stress when compared to conventional tungsten CVD processes. For example, in some implementations, the tungsten-fill CVD process includes heating the substrate to a temperature of about 250° C. or more, such as about 300° C. or more, or in a range from about 250° C. to about 500° C., or in a range from about 300° C. to about 500° C., or in a range from about 300° C. to about 400° C. During the deposition process of operation 360, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In another implementation, the metal-fill material 470 is deposited at operation 370 using an atomic layer deposition (ALD) process. The metal-fill ALD process includes repeating cycles of alternately exposing the semiconductor device structure 200 to a metal-containing precursor gas, for example, a tungsten-containing precursor gas, and a reducing agent and purging the processing region between the alternating exposures.

In another implementation, the metal-fill material 470 is deposited using a pulsed CVD method that includes repeating cycles of alternately exposing the semiconductor device structure 400 to a tungsten-containing precursor gas and a reducing gas without purging the processing region.

Referring to FIG. 4G, the completed metal-fill of the feature 422 is shown. As shown in FIG. 4G, the BN interface layer 460 enables seamless bottom-up growth of the metal-fill material 470. In some implementations, the one or more conformal/nonconformal layers 430, the nucleation layer 440, the BN interface layer 460, and the metal-fill material 470 are monolithic and do not have an interface therebetween. The metal-fill material 470, the one or more conformal/nonconformal layers 430, the nucleation layer 440, and the BN interface layer 460 together may form a tungsten-containing layer.

Referring to FIG. 4H, optionally at operation 380, the semiconductor device structure 400 may be exposed to additional processing. In some implementations, the additional processing includes a planarization process, for example a chemical mechanical polishing (CMP) process or an etchback process may be performed to remove excess portions or overburden of the conductive material (if present) on the upper surface 420u of the dielectric layer 420. After completing the planarization process, a top surface 464 of the metal-fill material 470 may be co-planar or level with the upper surface 420u of the dielectric layer and the top surfaces of the one or more conformal/nonconformal layers 430 as is shown in FIG. 2F. In some implementations, an annealing process may be performed during operation 380.

In some implementations, operations 340-370 are performed in the same processing chamber, for example, a PECVD chamber. In some implementations, operations 320-380 are performed in the same multi-chamber processing system without breaking vacuum. For example, operation 320 can be performed in a first chamber, for example, a PVD chamber, operation 330 is performed in a second chamber, for example, an ALD chamber, and operations 340-370 can be performed in a third chamber, for example, a PECVD chamber.

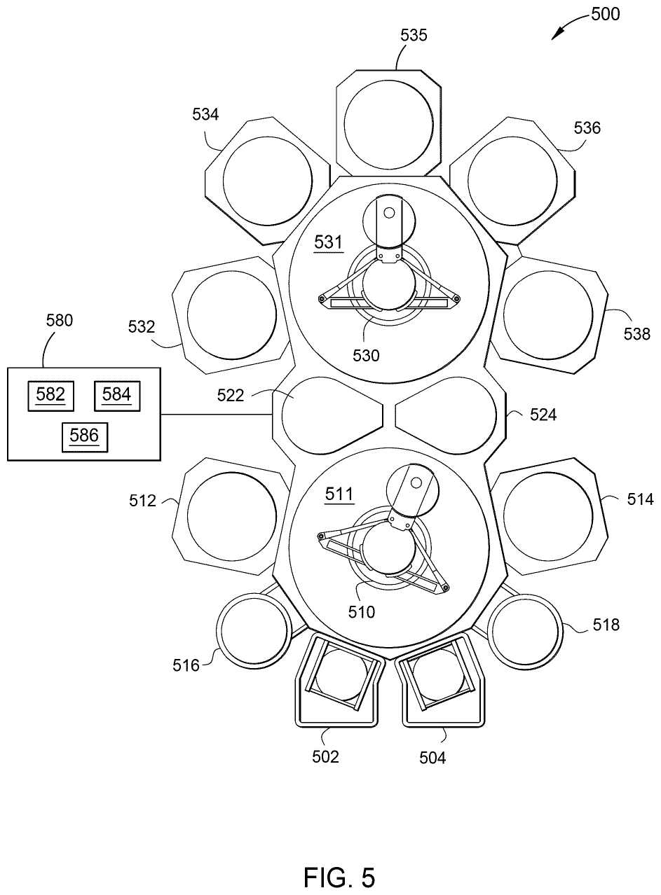

FIG. 5 illustrates a schematic top-view diagram of an example multi-chamber processing system 500 or cluster tool that can be used for deposition of a tungsten liner followed by seamless gap-fill of tungsten without breaking vacuum in accordance with one or more implementations of the present disclosure. The processing system 500 can include one or more load-lock chambers 502, 504 for transferring substrates into and out of the processing system 500. Typically, since the processing system 500 is under vacuum, the load-lock chambers 502, 504 may “pump down” the substrate introduced into the processing system 500. As shown in FIG. 5, a first set of one or more substrate processing chambers 512, 514, 516, 518 (four are shown) are coupled with a first transfer chamber 511. A first transfer robot 510 positioned in the first transfer chamber 511 transfers the substrates between the load-lock chambers 502, 504, and the first set of one or more substrate processing chambers 512, 514, 516, 518. Each substrate processing chamber 512, 514, 516, 518, can be outfitted to perform a number of substrate processing operations including the tungsten deposition processes and nitrogen treatment processes described herein in addition to cyclical layer deposition (CLD), atomic layer deposition (ALD), chemical vapor deposition (CVD), physical vapor deposition (PVD), plasma-enhanced chemical vapor deposition (PECVD), etch, pre-clean, degas, orientation and other substrate processes.

The first transfer robot 510 can also transfer substrates to/from one or more pass-through chambers 522, 524. The one or more pass-through chambers 522, 524 can be used to maintain ultrahigh vacuum conditions while allowing substrates to be transferred within the processing system 500. As also shown in FIG. 5, a second set of one or more substrate processing chambers 532, 534, 535, 536, and 538 are coupled with a second transfer chamber 531. A second transfer robot 530 positioned in the second transfer chamber 531 can transfer the substrates between the one or more pass-through chambers 522, 524 and a second set of one or more processing chambers 532, 534, 535, 536, and 538. Similar to the substrate processing chambers 512, 514, 516, 518, the substrate processing chambers 532, 534, 535, 536, and 538 can be outfitted to perform a variety of substrate processing operations including the tungsten deposition processes and nitrogen treatment processes described herein in addition to CLD, ALD, CVD, PECVD, PVD, etch, pre-clean, degas, and orientation, for example. Any of the substrate processing chambers 512, 514, 516, 518, 532, 534, 535, 536, and 538 may be removed from the processing system 500 if not necessary for a particular process to be performed by the processing system 500.

A system controller 580 is coupled to the processing system 500 for controlling the processing system 500 or components thereof. For example, the system controller 580 may control the operations of the processing system 500 using a direct control of the substrate processing chambers 512, 514, 516, 518, 532, 534, 535, 536, and 538 of the processing system 500 or by controlling controllers associated with the substrate processing chambers 512, 514, 516, 518, 532, 534, 535, 536, and 538. In operation, the system controller 580 enables data collection and feedback from the respective chambers to coordinate performance of the processing system 500.

The system controller 580 generally includes a central processing unit (CPU) 582, memory 584, and support circuits 586. The CPU 582 may be one of any form of a general purpose processor that can be used in an industrial setting. The memory 584, non-transitory computer-readable medium, or machine-readable storage device, is accessible by the CPU 582 and may be one or more of memory such as random access memory (RAM), read only memory (ROM), or any other form of digital storage, local or remote. The support circuits 586 are coupled to the CPU 582 and may comprise cache, clock circuits, input/output subsystems, power supplies, and the like. The various implementations disclosed in the present disclosure may generally be implemented under the control of the CPU 582 by executing computer instruction code stored in the memory 584 (or in memory of a particular processing chamber) as, for example, a computer program product or software routine. That is, the computer program product is tangibly embodied on the memory 584 (or non-transitory computer-readable medium or machine-readable storage device). When the computer instruction code is executed by the CPU 582, the CPU 582 controls the chambers to perform operations in accordance with the various implementations.

The instructions in memory 584 are in the form of a program product, such as a program that implements the methods of the present disclosure. In one example, the disclosure may be implemented as a program product stored on computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 580 is configured to perform methods such as the method 100 or the method 300 stored in the memory 584.

In particular implementations, at least one of the substrate processing chambers 512, 514, 516, 518, 532, 534, 535, 536, and 538 is a PECVD chamber configured to perform the BN interface layer formation of operations 340-360 and the tungsten deposition process of operation 370 of the methods 300 and another of the substrate processing chambers 512, 514, 516, 518, 532, 534, 535, 536, and 538 is an ALD chamber configured to perform the nucleation layer formation of operation 330 of the method 300 without breaking vacuum between any of the operations 330-370.

In operation, a substrate having a feature formed therein may be transferred to a first processing chamber, which is one of the substrate processing chambers 512, 514, 516, 518, 532, 534, 535, 536, and 538 where a liner layer is formed over the feature. The substrate may then be transferred to a second processing chamber which is one of the substrate processing chambers 512, 514, 516, 518, 532, 534, 535, 536, and 538 without breaking vacuum, where a nucleation layer is formed, for example, a tungsten nucleation layer. The substrate may then be transferred to a third processing chamber which is one of the substrate processing chambers 512, 514, 516, 518, 532, 534, 535, 536, and 538 without breaking vacuum, where the nucleation layer is exposed to a boron treatment, followed by a boron soak, followed by bottom-up metal growth.

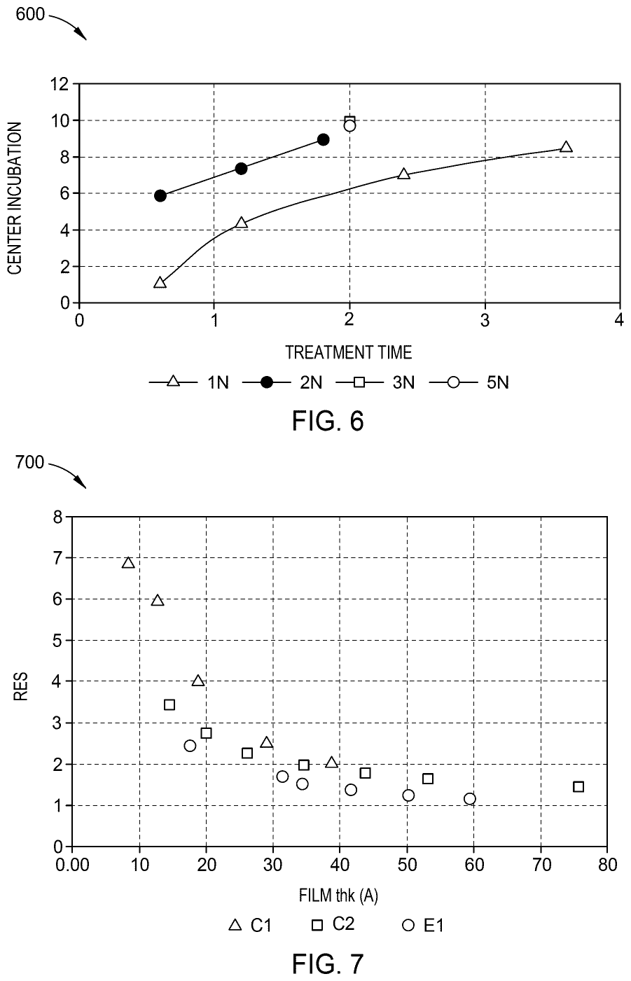

FIG. 6 depicts a graph 600 illustrating the effect of adjusting the nitrogen concentration during the N-treatment process on incubation time of the deposited tungsten film. Adjusting the nitrogen concentration during the nitrogen treatment process, as shown by the 1N-5N curves, can be used to tune the gap-fill process to meet the deposition process requirements need to fill different types of device structures. The curves depicted in FIG. 6 illustrate a process window that can be used to tailor the fill process for different types of device structures. As shown, the curves demonstrate an incubation time that generally increases on a formed boron nitride surface as the concentration of nitrogen was increased during the nitrogen treatment process. For example, the concentration of nitrogen used during the nitrogen treatment process was increased as the flow rates was increased from 1N to 5N. Not to be bound by theory but it is believed that by controlling the amount of boron soak dosage, the portion of the WN that will react with the boron precursor to form BN on metal nitride layer can be controlled. The unreacted WN provides the inhibition for the following metal growth and, hence, preserves the seam suppression capability.

FIG. 7 depicts a graph 700 illustrating the resistivity benefit provided by different process sequences. It has been found that W grown on BN interface layer will include large planar grains. “C1” represents a seam suppressed tungsten process. “C2” represents a CVD tungsten process. “E1” represents tungsten growth on a BN interface layer as described herein. Such large grains reduced the electron scattering at the grain boundary and showed a lower resistivity than traditionally formed W films (conformal CVD W or SSW), as shown in FIG. 7. Such resistivity benefit was confirmed in thin film region (<500 A) and bulk metal region (>2000 A).

The previously described implementations of the present disclosure have many advantages. The BN interface layer has intrinsic mesopores, which can provide a template for other applications including energy storage, optical modulation, DNA sequencing, and quantum information technologies. The BN interface layer also has low dangling bonds, which provides a good substrate for chemical reactions. The BN interface layer can also change the surface of metal from hydrophilic to hydrophobic. The cycles of N plasma and boron soaking can be repeated to increase the thickness of BN cap. Multiple BN interface layers can be stacked with weak Van der Waals bonds that can be a surface coat with low friction and lubrication. BN interface layer with a large bandgap (>5.5 eV) can serve as insulator layer or dielectric layers for semiconductor devices. BN cap provides good oxygen insulation cap from exposing the metal surface to atmosphere. However, the present disclosure does not necessitate that all the advantageous features and all the advantages need to be incorporated into every implementation of the present disclosure.

In the Summary and in the Detailed Description, and the claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect or implementation of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises,” “including,” and “having” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

While the foregoing is directed to implementations of the present disclosure, other and further implementations of the disclosure may be devised without departing from the basic scope thereof, and the scope thereof is determined by the claims that follow.

What is claimed is:

1. A method of forming a boron nitride layer on a metal surface, comprising:
exposing a surface of a metal layer to a nitrogen-containing plasma to form a metal nitride layer on the surface; and
performing a chemical vapor deposition (CVD) soak process in which the metal nitride layer is exposed to a boron containing precursor gas to, forming a boron nitride monolayer.

2. The method of claim 1, wherein the metal is tantalum, cobalt, titanium, tungsten, copper, ruthenium, molybdenum, or a combination thereof.

3. The method of claim 1, wherein the nitrogen-containing plasma is formed from a process gas comprising a nitrogen-containing gas.

4. The method of claim 3, wherein the nitrogen-containing gas is N2, NO, NO2, NH3, N2H4, or a combination thereof.

5. The method of claim 3, wherein the process gas further comprises an inert gas.

6. The method of claim 5, wherein the inert gas is argon, helium, or a combination thereof.

7. The method of claim 1, wherein the metal layer is a nucleation layer formed on a surface of a high aspect ratio feature.

8. The method of claim 1, wherein the metal layer is a capping layer.

9. The method of claim 1, further comprising repeating for a number of cycles exposing the surface of the metal layer to the nitrogen-containing plasma and performing the CVD soak process to form a three-dimensional boron nitride layer.

10. The method of claim 1, wherein the boron containing precursor gas is diborane, Triethylborane, Diethylborane, borazine (B3H6N3), or a combination thereof.

11. A method of filling a feature, comprising:
forming a nucleation layer over a surface of a feature formed in a surface of a substrate, wherein
the nucleation layer comprises a metal and the metal is tungsten, molybdenum, or cobalt,
the surface of the feature has a bottom surface and a sidewall surface, and
the sidewall surface has a bottom portion and a top portion which is above the bottom portion;
exposing the formed nucleation layer to a nitrogen-containing plasma to form a metal nitride layer on the surface of the nucleation layer, wherein the metal nitride layer comprises a gradient in nitrogen composition from the top portion to the bottom portion of the sidewall surface;
forming a boron nitride layer on the formed metal nitride layer by soaking the formed metal nitride layer in a first amount of a boron containing precursor gas; and
exposing the substrate to a metal-containing precursor gas and a reducing agent to form a metal fill layer over the formed boron nitride layer, wherein the metal fill layer comprises a metal and the metal is tungsten, molybdenum, cobalt, or a combination thereof.

12. The method of claim 11, wherein the nitrogen-containing plasma is formed from a process gas comprising a nitrogen-containing gas.

13. The method of claim 12, wherein the nitrogen-containing gas is N2, NO, NO2, NH3, N2H4, or a combination thereof.

14. The method of claim 13, wherein the process gas further comprises an inert gas.

15. The method of claim 14, wherein the inert gas is argon, helium, or a combination thereof.

16. The method of claim 11, further comprising forming a liner layer on the surface of the feature prior to forming the nucleation layer.

17. The method of claim 11, wherein the boron nitride layer is a boron nitride monolayer.

18. A method of filling a feature, comprising:
forming a tungsten nucleation layer over a surface of a feature formed in a surface of a substrate, wherein
the surface of the feature has a bottom surface and a sidewall surface, and
the sidewall surface has a bottom portion and a top portion which is above the bottom portion;
exposing the tungsten nucleation layer to a nitrogen-containing plasma to form a tungsten nitride layer on the surface of the tungsten nucleation layer, wherein the tungsten nitride layer comprises a gradient in nitrogen composition from the top portion to the bottom portion of the sidewall surface and the nitrogen-containing plasma is formed from a process gas comprising ammonia;
forming a boron nitride layer on the tungsten nitride layer by soaking the tungsten nitride layer in a first amount of diborane; and
exposing the substrate to a tungsten-containing precursor gas and a reducing agent to form a tungsten fill layer over the boron nitride layer.

19. The method of claim 18, further comprising forming a liner layer on the surface of the feature prior to forming the tungsten nucleation layer.

20. The method of claim 18, wherein the boron nitride layer is a boron nitride monolayer.
